(19) United States
(12) Patent Application Publication
(10) Pub. No.: US 2008/0299747 A1
(43) Pub. Date: Dec. 4, 2008

(54) METHOD FOR FORMING AMORPHOUSE SILICON FILM BY PLASMA CVD

(75) Inventors: Hirofumi ARAI, Tokyo (JP); Takashige WATANABE, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K., Tokyo (JP)

(21) Appl. No.: 11/755,432

(22) Filed: May 30, 2007

(51) Int. Cl. H01L 21/20

(52) U.S. Cl. 438/485; 257/E21.09

(57) ABSTRACT

A method includes introducing a silicon-containing source gas and a dilution gas to a reactor to deposit an amorphous silicon film on a substrate by plasma CVD; and adjusting a compressive film stress to 300 MPa or less and a uniformity of film thickness within the substrate surface to ±5% or less of the amorphous silicon film depositing on the substrate as a function of a flow rate of the source gas, a flow rate of the dilution gas, and a pressure of the reactor which are used as control parameters.

### BACKGROUND OF THE INVENTION

1. Field of the Invention

The present invention generally relates to a method for forming an amorphous silicon film by plasma CVD having a low compressive film stress and a high uniformity of film thickness.

2. Description of the Related Art

Amorphous silicon films are widely used as intermediate films in semiconductor processes, such as the manufacturing process for thin film transistors (TFT) and the production of field emission displays (FED) for liquid crystal devices. In recent years, amorphous silicon films are also finding a promising application as hard masks for metal gates in the dual-metal gate process. In this integration process, the step in which the first metal is etched requires that metal be removed completely without damaging the high-k insulation film, while the step in which the hard mask is removed calls for a certain selection ratio between the underlying metal and high-k insulation film. Amorphous silicon films are considered effective as hard masks in that they have high selectivity for wet etching materials that do not damage high-k insulation films.

As disclosed in Japanese Patent Laid-open No. 2003-92409, one film characteristic required of amorphous silicon films in TFT production is that the film stress of the amorphous silicon film be controlled to a level close to the film stress of the underlying insulation film, in order to increase the field effect and mobility of TFT. In traditional processes, the film stress of the insulation film is controlled to a level close to the film stress of the amorphous silicon film. However, it is more beneficial to be able to also control the film stress of the amorphous silicon film with ease. In the meantime, amorphous silicon films are used to form very thick layers in FED production and therefore, as disclosed in Japanese Patent Laid-open No. 2000-297372, the film stress of the amorphous silicon film must be controlled to a low level in order to prevent warping of the glass substrate and peeling of the film. As a means for controlling the film stress, traditionally methods are used whereby PH₃, NH₃ and other additive gases are mixed with the film forming gases to control the film stress of the amorphous silicon film along with the film's resistivity. However, these conventional technologies require that additive gases, such as PH₃ and NH₃, be used as essential components in addition to the source gas and dilution gas in order to control the resistivity and film stress of the amorphous silicon film.

### SUMMARY OF THE INVENTION

The present invention provides a new method for controlling the film stress of an amorphous silicon film. In an embodiment of the present invention, the film stress of an amorphous silicon film is controlled over a wide range only by means of the flow rate of the source gas, flow rate of the dilution gas, and film forming pressure, without using any additive gas. In general, a low film stress (“low film stress” means that the absolute stress value is small, and does not mean that the negative value of compressive stress is large) leads to deterioration in the uniformity of in-plane film thickness, which makes it difficult to improve both the film stress and uniformity of in-plane film thickness at the same time. By using the aforementioned control method, however, the in-plane uniformity can be adjusted by controlling the flow rate of the source gas, flow rate of the dilution gas, and film forming pressure. Furthermore, the flow rate of the source gas, flow rate of the dilution gas, and film forming pressure can be used as control parameters to improve the film stress without changing the uniformity of in-plane film thickness that has already been optimized.

In an embodiment, control of the flow rate of the dilution gas is more important than the other control parameters mentioned above. Specifically, when the flow rate of the source gas and film forming pressure are set to specific levels or greater, controlling the flow rate of the dilution gas allows for appropriate adjustment of the film stress and uniformity of in-plane film thickness.

In an embodiment, SiH₄ is used as a source gas, while He and/or H₂ is used as a dilution gas. In an embodiment, only SiH₄ and He and/or H₂ are used as gases. If the flow rate of He is controlled for the purpose of controlling the film stress, the currently available hardware may induce discharge at the upper electrode, which is not required in the film forming process, when the flow rate of He is 2,000 cc or higher. Such discharge at the upper electrode can cause production of foreign substances. In an embodiment, the dilution gas (such as He or H₂) is controlled within a range of approx. 500 sccm to approx. 1,000 sccm, so that the film stress can be lowered, while the uniformity of in-plane film thickness is improved, without causing the aforementioned problem.

As explained above, according to an embodiment of the present invention an amorphous silicon film can be formed on a substrate by plasma CVD in such a way that its film stress can be controlled to a desired level over a wide range in accordance with the purpose of each semiconductor device (whether the device is used for a conventional purpose or any new purpose that may be developed in the future), only by adjusting the flow rate of SiH₄ used as a source gas, film forming pressure, and flow rate of He or H₂ used as a dilution gas, without using any new additive gas.

For purposes of summarizing the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description of the preferred embodiments which follow.

### BRIEF DESCRIPTION OF THE DRAWINGS

These and other features of this invention will now be described with reference to the drawings of preferred embodiments which are intended to illustrate and not to limit the invention. The drawings are oversimplified for illustrative purposes and are not to scale.

FIG. 1 is a graph showing the relationship between film stress and RC (reaction chamber) pressure according an embodiment of the present invention.

FIG. 2 is a graph showing the relationship between film stress and He gas flow rate according an embodiment of the present invention.

FIG. 3 is a graph showing the relationship between uniformity of thickness and RC pressure according an embodiment of the present invention.

FIG. 4 is a graph showing the relationship between uniformity of thickness and He gas flow rate according an embodiment of the present invention.

FIG. 5 is a graph showing the relationship between uniformity of thickness/film stress and SiH₄ gas flow rate according an embodiment of the present invention.

FIG. 6 is a graph showing the relationship between uniformity of thickness and gas (H₂ or He) flow rate according an embodiment of the present invention.

FIG. 7 is a graph showing the relationship between film stress and gas (H₂ or He) flow rate according an embodiment of the present invention.

### DETAILED DESCRIPTION OF THE PREFERRED EMBODIMENT

The present invention will be explained in detail with reference to preferred embodiments. However, the preferred embodiments are not intended to limit the present invention.

According to an embodiment, a method for forming an amorphous silicon film on a substrate by plasma CVD which has a compressive film stress of 300 MPa or less and a uniformity of film thickness within the substrate surface of ±5% or less, comprises: (i) introducing a silicon-containing source gas and a dilution gas to a reactor to deposit an amorphous silicon film on a substrate by plasma CVD; and (ii) adjusting a compressive film stress to 300 MPa or less and a uniformity of film thickness within the substrate surface to ±5% or less of the amorphous silicon film depositing on the substrate as a function of a flow rate of the source gas, a flow rate of the dilution gas, and a pressure of the reactor which are used as control parameters.

In the above embodiment, the step of adjusting the film stress and the uniformity of film thickness may exclusively use the flow rate of the source gas, the flow rate of the dilution gas, and the pressure of the reactor as control parameters.

In any of the foregoing embodiments, the source gas may be SiH₄ and the dilution gas may be He and/or H₂.

In any of the foregoing embodiments, the flow rate of the source gas may be controlled at 60 sccm or higher, the flow rate of the dilution gas may be controlled at 300 sccm to 1,500 sccm, and the pressure of the reactor may be controlled at 6.0 Torr or higher.

In any of the foregoing, the dilution gas may be He and its flow rate may be controlled at 300 sccm to 1,000 sccm.

In any of the foregoing embodiment, the dilution gas may be H₂ and its flow rate may be controlled at 500 sccm to 1,500 sccm.

In any of the foregoing embodiment, the source gas may consist of SiH₄ and the dilution gas may consist of He and/or H₂, wherein no other gas may be used.

In any of the foregoing embodiment, the flow rate of SiH₄ may be controlled at 60 sccm to 120 sccm.

In any of the foregoing embodiment, the pressure of the reactor may be controlled at 6.0 Torr to 8.0 Torr.

In another embodiment, a method for forming an amorphous silicon film on a substrate by plasma CVD, comprises: (i) introducing a silicon-containing source gas and a dilution gas of He and/or H₂ to a reactor to deposit an amorphous silicon film on a substrate by plasma CVD; and (ii) controlling a flow rate of the source gas at 60 sccm or higher, a flow rate of the dilution gas at 500 sccm to 1,000 sccm, and a pressure of the reactor at 6.0 Torr or higher.

In the above embodiment, the source gas may be SiH₄.

In any of the foregoing embodiment, the step of controlling the flow rate of the source gas, the flow rate of the dilution gas, and the pressure of the reactor may control the flow rate of the source gas, the flow rate of the dilution gas, and the pressure of the reactor so as to adjust a compressive film stress to 300 MPa or less and a uniformity of film thickness within the substrate surface to ±5% or less of the amorphous silicon film depositing on the substrate as a result of the foregoing control.

In any of the foregoing embodiment, the step of adjusting the film stress and the uniformity of film thickness may exclusively use the flow rate of the source gas, the flow rate of the dilution gas, and the pressure of the reactor as control parameters.

In any of the foregoing embodiment, the dilution gas may be He and its flow rate may be controlled at 300 sccm to 1,000 sccm.

In any of the foregoing embodiment, the dilution gas may be H₂ and its flow rate may be controlled at 500 sccm to 1,500 sccm.

In any of the foregoing embodiment, the source gas may consist of SiH₄ and the dilution gas may consist of He and/or H₂, wherein no other gas may be used.

In any of the foregoing embodiment, the flow rate of SiH₄ may be controlled at 60 sccm to 120 sccm.

In any of the foregoing embodiment, the pressure of the reactor may be controlled at 6.0 Torr to 8.0 Torr.

In still another embodiment, a method for forming an amorphous silicon film on a substrate by plasma CVD which has a compressive film stress of 300 MPa or less and a uniformity of film thickness within the substrate surface of ±5% or less, comprises: (i) introducing a silicon-containing source gas and a dilution gas of He and/or H₂ to a reactor to deposit an amorphous silicon film on a substrate by plasma CVD, wherein a flow rate of the source gas is set at 60 sccm or higher and a pressure of the reactor is set at 6.0 Torr or higher; and (ii) adjusting a compressive film stress to 300 MPa or less and a uniformity of film thickness within the substrate surface to ±5% or less of the amorphous silicon film depositing on the substrate as a function of a flow rate of the dilution gas which is used as a control parameter.

In the above embodiment, the step of adjusting the film stress and the uniformity of film thickness may exclusively use the flow rate of the dilution gas as the control parameter.

In any of the foregoing embodiment, the source gas may be SiH₄.

In any of the foregoing embodiment, the flow rate of the dilution gas may be controlled at 300 sccm to 1,500 sccm.

In any of the foregoing embodiment, the dilution gas may be He and its flow rate may be controlled at 300 sccm to 1,000 sccm.

In any of the foregoing embodiment, the dilution gas may be H₂ and its flow rate may be controlled at 500 sccm to 1,500 sccm.

In any of the foregoing embodiment, the source gas may consist of SiH₄ and the dilution gas may consist of He and/or H₂, wherein no other gas may be used.

In any of the foregoing embodiment, the flow rate of SiH₄ may be controlled at 60 sccm to 120 sccm.

In any of the foregoing embodiment, the pressure of the reactor may be controlled at 6.0 Torr to 8.0 Torr.

In the present disclosure, in an embodiment, the amorphous silicon film may have a compressive film stress of 350 MPa or less (including 300 MPa, 250 MPa, 200 MPa, 150 MPa, and values between any two numbers of the foregoing; preferably 300 MPa or less). In an embodiment, the amorphous silicon film may have a uniformity of film thickness within the substrate surface of ±5% or less (including ±4%, ±3%, ±2%, and values between any two numbers of the foregoing; preferably ±3% or less). In an embodiment, any combination of the above values of compressive film stress and the above values of uniformity of film thickness can be achieved.

In the present disclosure, in an embodiment, although the source gas may preferably be SiH₄, other silicon-containing gas may be used or added to the extent that the intended results are accomplished. In an embodiment, the flow rate of the source gas may be 40 sccm or more (including 50 sccm, 60 sccm, 80 sccm, 100 sccm, 120 sccm, 200 sccm, and values between any two numbers of the foregoing; preferably 60 sccm to 120 sccm). In an embodiment, although the dilution gas may preferably be He or H₂ or a mixture thereof, other inert gas may be used or added to the extent that the intended results are accomplished. In an embodiment, although the flow rate of the dilution gas may be 300 sccm to 1,500 sccm, when the dilution gas is He, the flow rate may be controlled at 300 sccm to 1,000 sccm (including 400 sccm, 500 sccm, 700 sccm, 900 sccm, and values between any two numbers of the foregoing; preferably 500 sccm to 1,000 sccm). In an embodiment, when the dilution gas is H₂, the flow rate may be controlled at 500 sccm to 1,500 sccm (including 600 sccm, 800 sccm, 1,000 sccm, 1,300 sccm, and values between any two numbers of the foregoing; preferably 750 sccm to 1,250 sccm).

In the present disclosure, in an embodiment, the reactor pressure may be 5.5 Torr or higher (including 6 Torr, 7 Torr, 8 Torr, 10 Torr, 20 Torr, and values between any two numbers of the foregoing; preferably 6 Torr to 8 Torr).

In an embodiment, other conditions may be as follows: RF frequency: 10-60 MHz; RF power: 200 W to 800 W; Temperature of lower electrode: 450° C. to 750° C.; Temperature of upper electrode: 130° C. to 180° C.; Temperature of inner wall of the rector: 115° C. to 165° C.; Distance between the upper and lower electrodes: 10 mm to 20 mm. In an embodiment, the thickness of the amorphous silicon film may be in the range of 10 nm to 300 nm (including 50 nm, 100 nm, 200 nm, and values between any two numbers of the foregoing).

In an embodiment, the amorphous silicon film may have an extinction coefficient of 0.16-0.20 and a refractive index of 3.5-4.5 at 633 nm.

In the present disclosure, the numerical numbers applied in embodiments can be modified by ±50% in other embodiments, and the ranges applied in embodiments may include or exclude the endpoints.

Further, in the present disclosure where conditions and/or structures are not specified, the skilled artisan in the art can readily provide such conditions and/or structures, in view of the present disclosure, as a matter of routine experimentation.

### EXAMPLES

The present invention will be explained with reference to preferred examples and drawings. However, the examples and drawings are not intended to limit the present invention.

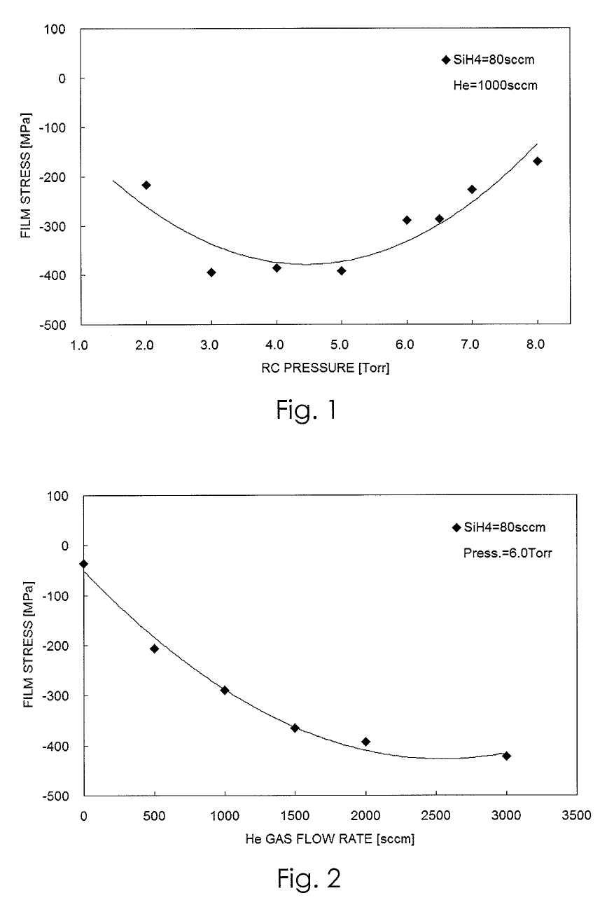

The best mode for carrying out the present invention is explained below by referring to Tables 1 and 3, and FIGS. 1 through 5. It is clear that, by forming an amorphous silicon film under the ranges of conditions shown in Table 1 and without using any separate additive gas, it becomes possible to control the film stress of the obtained film over a wide range. For your reference, other conditions used in the examples described below are shown in Table 3. Eagle® 12 manufactured by ASM Japan K.K. was used as the apparatus.

TABLE 1

| SiH4/sccm | He/slm | Pressure/Torr |
|---|---|---|
| 5~120 | 0.0~3.0 | 2.0~8.0 |

TABLE 2

| | | | | Wall | | |
|---|---|---|---|---|---|---|
| RF | | Lower | Upper | tem- | Distance | Film |
| fre- | RF | elec- | elec- | pera- | between | thick- |
| quency | power | trode | trode | ture | electrodes | ness |
| 13.56 MHz | 450 W | 600° C. | 155° C. | 140° C. | 14 mm | 100 nm |

FIG. 1 shows how the film stress changes with respect to the film forming pressure when the flow rate of SiH₄ is adjusted to 80 sccm. As shown in the figure, the film stress can be controlled over a wide range only by changing the film forming pressure. It is evident that use of a high film forming pressure (>6.0 Torr) or low film forming pressure (<2.0 Torr) is effective in achieving a low film stress on the tensile side of −300 MPa (i.e., a film stress whose absolute value on the compressive side is small).

Similarly, FIG. 2 shows how the film stress changes with respect to the flow rate of He when the flow rate of SiH₄ is adjusted to 80 sccm. Based on the result in FIG. 1 above, 6.0 Torr is used as the film forming pressure as this level of pressure is shown to provide a low film stress. Clearly, the film stress can also be controlled by changing only the flow rate of He, just like when the film forming pressure alone is changed. Evidently, use of a flow rate of 1,000 sccm or lower is effective in achieving a low film stress on the tensile side of −300 MPa.

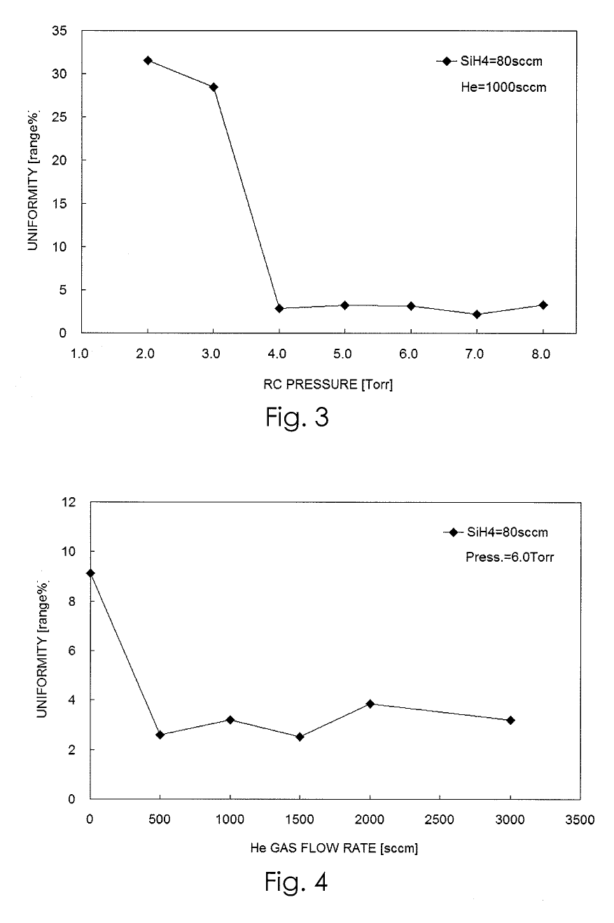

On the other hand, FIG. 3 and FIG. 4 show how the in-plane uniformity changes with respect to the film forming pressure and flow rate of He, respectively.

For your reference, the term “in-plane uniformity” here refers specifically to the uniformity of film thickness based on measurements taken at 49 points within the plane (3 mm was cut off from the edges). The measurement results were obtained using a spectroscopic ellipsometer manufactured by Woollam.

FIG. 3 shows how the in-plane uniformity changes when the film forming pressure changes at a SiH₄ flow rate of 80 sccm and He flow rate of 1,000 sccm. It is shown that a good in-plane uniformity can be achieved in a stable manner by using a film forming pressure of 4.0 Torr or higher. The upper-limit pressure is 8.0 Torr based on the measured data. Since standard film forming apparatuses typically use a 10 Torr gauge as the RC pressure gauge, 10 Torr is considered the maximum pressure at which evaluation is possible. When the trend data at low pressures is examined, attainment of stable film quality can also be expected at pressures of 8.0 Torr or higher. Here, the sudden change between 3.0 Torr and 4.0 Torr is likely explained by the instability of plasma at 3.0 Torr and lower pressures due to discharge induced at the upper electrode during the film forming process. In other words, an amorphous silicon film cannot be formed stably, and consequently the in-plane uniformity drops, in this range.

From the above findings, and also based on the measured result of change in film stress as shown in FIG. 1, use of a film forming pressure between 6.0 and 8.0 Torr is effective in achieving an amorphous silicon film having a low film pressure and good in-plane uniformity.

Similarly, FIG. 4 shows how the in-plane uniformity changes when the flow rate of He changes at a SiH₄ flow rage of 80 sccm and film forming pressure of 6.0 Torr. As evident from FIG. 4, use of He gas improves the in-plane uniformity significantly. This suggests that He is a dilution gas effective in improving the in-plane uniformity.

From the above findings, and also based on the measured result of change in film stress as shown in FIG. 2, use of a He flow rate of 500 to 1,000 sccm is effective in achieving an amorphous silicon film having a low film pressure and good in-plane uniformity.

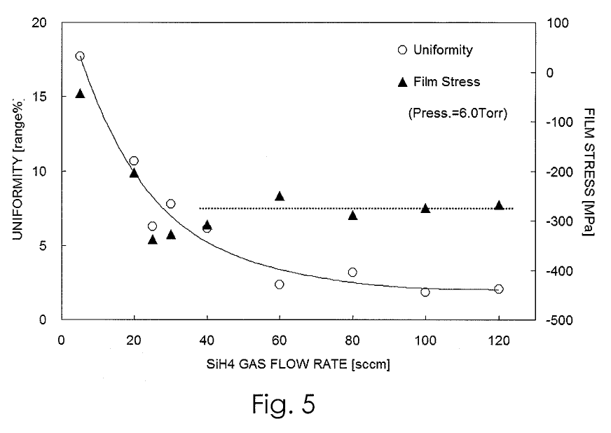

FIG. 5 shows how the film stress and in-plane uniformity of an amorphous silicon film change when the flow rate of SiH₄, used as a main source gas, is changed. As evident from FIG. 5, in this example increasing the flow rate of SiH₄ has the effect of improving the in-plane uniformity, while stably achieving a low film stress in the range of 60 sccm or higher. In other words, the in-plane uniformity of the amorphous silicon film, which already has a controlled low film stress achieved by a film forming pressure and He flow rate in the optimal ranges shown above, can be improved by optimally adjusting the flow rate of the SiH₄ source gas in a range of 60 sccm or higher, without having to change the film stress. Here, the upper limit of 120 sccm shown in the figure is based on the maximum SiH₄ flow rate measurable by the MFC of the apparatus used in the evaluation. Although good results are anticipated at flow rates higher than this level, concerns remain over unstable film quality resulting from a short film forming period used in processes where a thin film is formed due to a significant DR improvement.

Based on the above results, sample condition ranges are shown in Table 3 that represent the best mode for carrying out the present invention. When the conditions are controlled within these ranges, an amorphous silicon film having a good in-plane uniformity and low film stress can be formed. It should be noted, however, that this is only one example and the present invention is not at all limited to the ranges of values described herein.

TABLE 3

| SiH4/sccm | He/slm | Pressure/Torr |
|---|---|---|
| 60~120 | 0.5~1.0 | 6.0~8.0 |

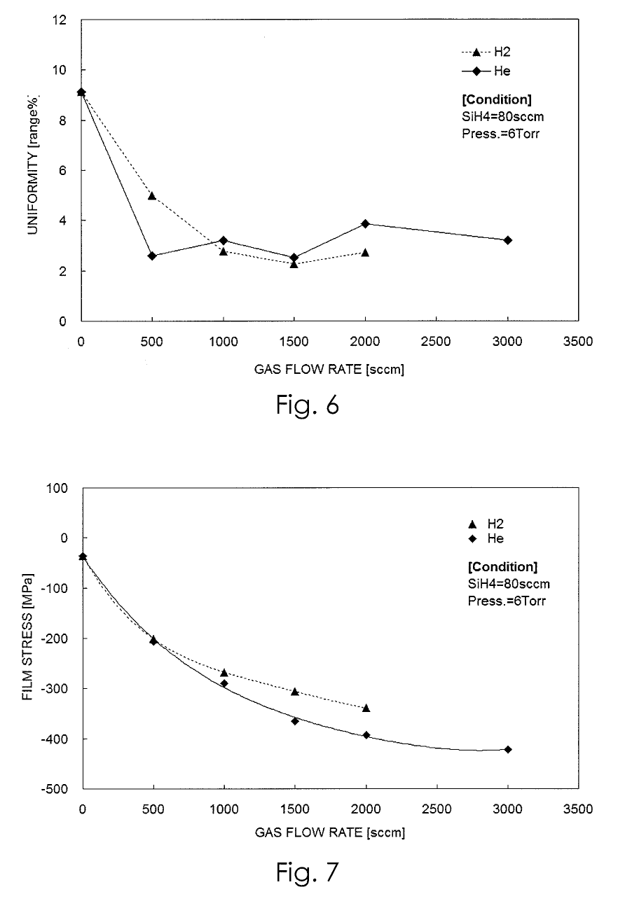

Next, a modified example is shown. FIG. 6 and FIG. 7 are graphs illustrating a modified example of the present invention.

FIG. 6 shows how the film stress changes when H₂ is used as a dilution gas, while FIG. 7 shows how the in-plane uniformity changes, both in comparison to the best mode of embodiment where He is used. Here, the flow rate of SiH₄ and film forming pressure are adjusted to 80 sccm and 6.0 Torr, respectively, both within the optimal condition ranges demonstrated in the best mode of embodiment.

As evident from FIG. 6, the in-plane uniformity also improves when H₂ is used as a dilution gas, just like when He is used. FIG. 7 also shows that the trend of film stress is roughly the same as when He is used.

From the above, H₂ can also be used as a dilution gas for SiH₄ gas in the forming of an amorphous silicon film. One advantage of using H₂ instead of He is that the dangling bond of Si in the formed amorphous silicon film can be terminated with a H atom to achieve stable film quality.

As explained above, the method for forming an amorphous silicon film according to any given embodiment of the present invention allows for easy control of film stress and improvement of in-plane uniformity in accordance with the purpose of each semiconductor device, only by changing the conditions for SiH₄ used as a reactant gas, He or H₂ used as a dilution gas, and film forming pressure, without using any new additive gas.

In the above examples, the numerical numbers specifically applied in the examples may be modified by ±50% in other embodiments, and the ranges applied in the examples may include or exclude the endpoints in other embodiments.

It will be understood by those of skill in the art that numerous and various modifications can be made without departing from the spirit of the present invention. Therefore, it should be clearly understood that the forms of the present invention are illustrative only and are not intended to limit the scope of the present invention.

What is claimed is:

1. A method for forming an amorphous silicon film on a substrate by plasma CVD which has a compressive film stress of 300 MPa or less and a uniformity of film thickness within the substrate surface of ±5% or less, comprising:
introducing a silicon-containing source gas and a dilution gas to a reactor to deposit an amorphous silicon film on a substrate by plasma CVD; and
adjusting a compressive film stress to 300 MPa or less and a uniformity of film thickness within the substrate surface to ±5% or less of the amorphous silicon film depositing on the substrate as a function of a flow rate of the source gas, a flow rate of the dilution gas, and a pressure of the reactor which are used as control parameters.

2. The method according to claim 1, wherein the step of adjusting the film stress and the uniformity of film thickness exclusively uses the flow rate of the source gas, the flow rate of the dilution gas, and the pressure of the reactor as control parameters.

3. The method according to claim 1, wherein the source gas is SiH₄ and the dilution gas is He and/or H₂.

4. The method according to claim 3, wherein the flow rate of the source gas is controlled at 60 sccm or higher, the flow rate of the dilution gas is controlled at 300 sccm to 1,500 sccm, and the pressure of the reactor is controlled at 6.0 Torr or higher.

5. The method according to claim 4, wherein the dilution gas is He and its flow rate is controlled at 300 sccm to 1,000 sccm.

6. The method according to claim 4, wherein the dilution gas is H₂ and its flow rate is controlled at 500 sccm to 1,500 sccm.

7. The method according to claim 1, wherein the source gas consists of SiH₄ and the dilution gas consists of He and/or H₂, wherein no other gas is used.

8. The method according to claim 4, wherein the flow rate of SiH₄ is controlled at 60 sccm to 120 sccm.

9. The method according to claim 4, wherein the pressure of the reactor is controlled at 6.0 Torr to 8.0 Torr.

10. A method for forming an amorphous silicon film on a substrate by plasma CVD, comprising:
introducing a silicon-containing source gas and a dilution gas of He and/or H₂ to a reactor to deposit an amorphous silicon film on a substrate by plasma CVD; and
controlling a flow rate of the source gas at 60 sccm or higher, a flow rate of the dilution gas at 500 sccm to 1,000 sccm, and a pressure of the reactor at 6.0 Torr or higher.

11. The method according to claim 10, wherein the source gas is SiH₄.

12. The method according to claim 10, wherein the step of controlling the flow rate of the source gas, the flow rate of the dilution gas, and the pressure of the reactor controls the flow rate of the source gas, the flow rate of the dilution gas, and the pressure of the reactor so as to adjust a compressive film stress to 300 MPa or less and a uniformity of film thickness within the substrate surface to ±5% or less of the amorphous silicon film depositing on the substrate as a result of the foregoing control.

13. The method according to claim 10, wherein the step of adjusting the film stress and the uniformity of film thickness exclusively uses the flow rate of the source gas, the flow rate of the dilution gas, and the pressure of the reactor as control parameters.

14. The method according to claim 10, wherein the dilution gas is He and its flow rate is controlled at 300 sccm to 1,000 sccm.

15. The method according to claim 10, wherein the dilution gas is H₂ and its flow rate is controlled at 500 sccm to 1,500 sccm.

16. The method according to claim 10, wherein the source gas consists of SiH₄ and the dilution gas consists of He and/or H₂, wherein no other gas is used.

17. The method according to claim 11, wherein the flow rate of SiH₄ is controlled at 60 sccm to 120 sccm.

18. The method according to claim 10, wherein the pressure of the reactor is controlled at 6.0 Torr to 8.0 Torr.

19. A method for forming an amorphous silicon film on a substrate by plasma CVD which has a compressive film stress of 300 MPa or less and a uniformity of film thickness within the substrate surface of ±5% or less, comprising:
introducing a silicon-containing source gas and a dilution gas of He and/or H₂ to a reactor to deposit an amorphous silicon film on a substrate by plasma CVD, wherein a flow rate of the source gas is set at 60 sccm or higher and a pressure of the reactor is set at 6.0 Torr or higher; and
adjusting a compressive film stress to 300 MPa or less and a uniformity of film thickness within the substrate surface to ±5% or less of the amorphous silicon film depositing on the substrate as a function of a flow rate of the dilution gas which is used as a control parameter.

20. The method according to claim 19, wherein the step of adjusting the film stress and the uniformity of film thickness exclusively uses the flow rate of the dilution gas as the control parameter.

21. The method according to claim 19, wherein the source gas is SiH₄.

22. The method according to claim 19, wherein the flow rate of the dilution gas is controlled at 300 sccm to 1,500 sccm.

23. The method according to claim 22, wherein the dilution gas is He and its flow rate is controlled at 300 sccm to 1,000 sccm.

24. The method according to claim 22, wherein the dilution gas is H₂ and its flow rate is controlled at 500 sccm to 1,500 sccm.

25. The method according to claim 19, wherein the source gas consists of SiH₄ and the dilution gas consists of He and/or H₂, wherein no other gas is used.

26. The method according to claim 21, wherein the flow rate of SiH₄ is controlled at 60 sccm to 120 sccm.

27. The method according to claim 19, wherein the pressure of the reactor is controlled at 6.0 Torr to 8.0 Torr.
